(19) United States
(12) Patent Application Publication
(10) Pub. No.: US 2010/0319765 A1
(43) Pub. Date: Dec. 23, 2010

(54) PHOTOVOLTAIC DEVICES

(75) Inventor: Dong Hoon CHOI, Seoul (KR)

Correspondence Address: Workman Nydegger;1000 Eagle Gate Tower, 60 East South Temple, Salt Lake City, UT, 84111, US

(73) Assignee: KOREA UNIVERSITY RESEARCH AND BUSINESS FOUNDATION, Seoul (KR)

(21) Appl. No.: 12/486,603

(22) Filed: Jun. 17, 2009

(51) Int. Cl. H01L 31/0352; H01L 31/18

(52) U.S. Cl. 136/256; 438/57; 257/E21.158; 257/E31.032

(57) ABSTRACT

A photovoltaic device includes a photoactive layer which has at least one embossed pattern on a surface thereof. This embossed pattern varies traveling directions of light in the photoactive layer.

### BACKGROUND

The conversion of solar energy into electrical energy is one of the prime technologies which can impact the world's future energy requirements as well as potentially solve the current and impending global warming problems caused by the increased usage of carbon-based energy sources. Development of efficient and low cost photovoltaic devices is key to increased utility of direct solar energy to electrical power conversion.

Traditionally, inorganic semiconductor materials have been used in commercial photovoltaic cells to convert incident light energy into electrical energy. In addition, certain conjugated polymers and electroactive organic materials have been found to also exhibit semiconductor-like properties and, thus, are being employed in similar photovoltaic devices to convert solar energy to electrical energy. One major drawback to the production of classical photovoltaic devices (e.g., photovoltaic devices based on inorganic semiconductor materials) is the expensive investment due to costly semiconductor processing technologies.

Organic-based solar cells have received recent interest for use in photovoltaic devices. These devices employ thin films of electroactive organic materials between electrodes, of which at least one electrode is transparent to incident light (e.g., sun light). Although organic-based photovoltaic devices offer specific fabrication and economic advantages over the traditional, classical photovoltaic devices, fail to provide comparable power conversion efficiencies as compared to the classical photovoltaic devices.

### SUMMARY

Various embodiments of photovoltaic devices and techniques for manufacturing the photovoltaic devices are disclosed herein. In one embodiment, a photovoltaic device includes a photoactive layer which has at least one embossed pattern on a surface thereof.

In another embodiment, a photovoltaic device includes a first electrode, a second electrode, and a photoactive layer which may be positioned between the first electrode and the second electrode and may include an embossed pattern on a surface thereof.

In still another embodiment, a method for manufacturing a photovoltaic device includes preparing a hole transport layer, patterning an embossed pattern on a surface of the hole transport layer, and forming a photoactive layer on the embossed pattern.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE FIGURES

FIG. 1 shows a schematic diagram of an illustrative embodiment of a photovoltaic device.

FIGS. 2A, 2B and 2C show illustrative embodiments of embossed patterns formed on a surface of a hole transport layer.

FIG. 3 shows an illustrative embodiment of a photoactive layer.

FIG. 4 shows another illustrative embodiment of a photoactive layer.

FIGS. 5A to 5E show an illustrative embodiment of a method for manufacturing a photovoltaic device.

FIG. 6 shows a schematic diagram of another illustrative embodiment of a photovoltaic device.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

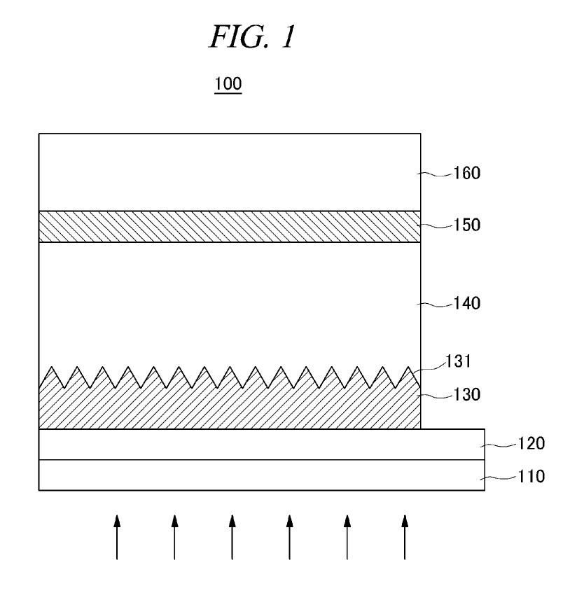

In one aspect, the present disclosure provides a photovoltaic device including a photoactive layer which has at least one embossed pattern on a surface thereof. FIG. 1 is a schematic diagram of an illustrative embodiment of a photovoltaic device 100. The photovoltaic device 100 may include, for example, a transparent substrate 110, a first electrode 120, a hole transport layer 130, a photoactive layer 140, an electron transport layer 150 and a second electrode 160.

The transparent substrate 110 can be made of a light-transmissive material such as, but not limited to, glass, polycarbomate, poly methylmethacrylate, polystyrene, polyethylene terephthalate, or polyethylene naphthalate. An incident light can be irradiated onto the transparent substrate 110.

The first electrode 120 may be formed on the transparent substrate 110. The first electrode 120 can be made of a transparent conductive oxide (TCO) such as, but not limited to, indium tin oxide (ITO), indium zinc oxide (IZO) or fluorine-doped tin oxide (FTO). For example, the first electrode 120 may serve as an anode for a hole injection.

The hole transport layer 130 may be formed on the first electrode 120. The hole transport layer 130 may include a conjugated polymer such as, but not limited to, poly-3,4-ethylenedioxythiophene(PEDOT):poly-styrenesulfonate (PSS), polyaniline, phthalocyanine or derivatives thereof, or a combination including at least one of the foregoing polymers. For example, the hole transport layer 130 can be made of a PEDOT:PSS which is prepared by blending PEDOT with PSS at a ratio of about 1:1.

The hole transport layer 130 may have conductivity and its work function may fall between a work function of the first electrode 120 and a work function of the photoactive layer 140. Therefore, the hole transport layer 130 enables holes to be transported from the photoactive layer 140 to the first electrode 120. Further, when forming the photoactive layer 140 later, the hole transport layer 130 may serve to protect the first electrode 120.

An embossed pattern 131 may be formed on an upper surface of the hole transport layer 130. The embossed pattern 131 may change a traveling direction of light incident to the embossed pattern 131 to various other directions.

The photoactive layer 140 may be formed on the embossed pattern 131 of the hole transport layer 130. Accordingly, the photoactive layer 140 may have an embossed pattern corresponding to the embossed pattern 131 on a lower surface thereof. The photoactive layer 140 can be made of, for example, a molecular or polymer organic material.

In some embodiments, the electron transport layer 150 may be formed on the photoactive layer 140. The electron transport layer 150 enables electrons to be transported from the photoactive layer 140 to the second electrode 160. Further, the electron transport layer 150 may also serve to protect the photoactive layer 140 when forming the second electrode 160. The electron transport layer 150 may be made of, for example, LiF or Li₂O. The electron transport layer 150 is optional and may be omitted in certain embodiments.

The second electrode 160 may be formed on the electron transport layer 150. The second electrode 160 can be made of a conductive material such as, but not limited to, Al, Ti, W, Ag, Au, combinations thereof, and the like. However, the material used for the second electrode 160 is not limited thereto, and any material having a work function lower than that of the first electrode 120 can be employed. The second electrode 160 may serve as, for example, a cathode for an electron injection. If the electron transport layer 150 is omitted as discussed above, the second electrode 160 may be formed on the photoactive layer 140.

Depending on molecular structures of and manufacturing processes used to create the photoactive layer 140, a particular region in the photoactive layer 140 may readily absorb light traveling in a certain direction. Therefore, if the light incident on a lower surface of the photoactive layer 140 travels in a single direction within the photoactive layer 140, this light is more readily absorbed in a particular region in the photoactive layer 140, whereas this light is not readily absorbed in other regions in the photoactive layer 140. Accordingly, if the light does not travel in various (or numerous) directions but in one direction (i.e., the light travels in a single direction), the photoactive layer 140 may not be able to sufficiently absorb the light.

For example, if the upper surface of the hole transport layer 130 is smooth and planar, incident light travels in a relatively straight direction following the Snell's law as it passes through the photoactive layer 140. Therefore, the incident light can not be sufficiently absorbed in the photoactive layer 140 because the incident light does not travel in various directions (i.e., the incident light traveling in a relatively straight direction does not have multiple paths.

In some embodiments, the embossed pattern 131 is formed at the upper surface of the hole transport layer 130. The embossed pattern 131 functions to vary the traveling directions of light incident to the embossed pattern 131 as it travels or propagates through the photoactive layer 140. The various directions of light paths are induced in the photoactive layer 140 by multiple diffractions, refractions or reflections of the incident light. Due to these various directions of light paths, the traveling distance of the light in the photoactive layer 140 is increased. Accordingly, the light absorption property of the photoactive layer 140 is also enhanced as a result of the increase in the distance of the light that is propagating through the photoactive layer 140.

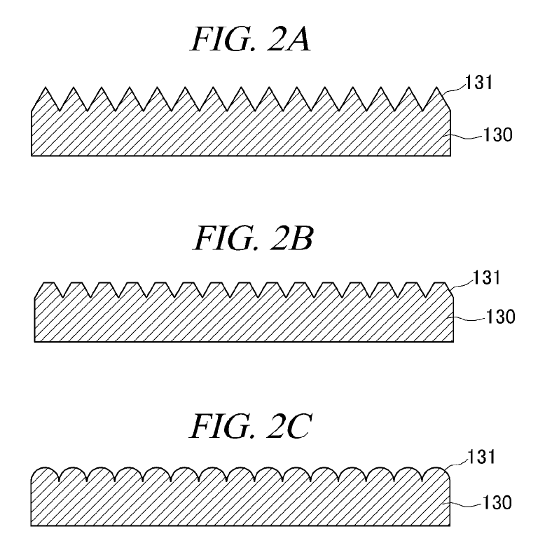

FIGS. 2A to 2C show various illustrative embodiments of the embossed pattern 131. The embossed pattern 131 may have various patterns or shapes such as, by way of example, a triangular embossed pattern (FIG. 2A), a substantially rectangular embossed pattern, a polygonal embossed pattern (FIG. 2B), a semicircular embossed pattern (FIG. 2C), and the like. The embossed pattern 131 is designed to induce the multiple diffractions, refractions or reflections of incident light. Therefore, the embossed pattern 131 is not limited to the examples shown in FIGS. 2A to 2C, but includes other kinds of patterns capable of inducing the multiple diffractions, refractions or reflections of the incident light.

Further, the photoactive layer 140 may include an electron donating region and an electron accepting region As a non-limiting example, the electron donating region may be made of a p-type semiconductive polymer, oligomer, small molecules, or dendrimer material such as, but not limited to, poly(3-hexylthiophene) (P3HT), poly(1-methoxy-4-(O-disperse Red 1)-2,5-phenylene-vinylene, polyindole, polycarbazole, polyp yridiazine, polyisothianaphthalene, polyphenylene sulfide, polyfluorene or derivatives thereof, or a combination including at least one of the foregoing conductive polymers. The material for the electron donating region is not limited to the aforementioned examples, and any material or mixture having a work function lower than that of the hole transport layer 130 can be used.

The electron accepting region may be composed of, by way of example, but not limitation, fullerene or derivatives thereof, nanocrystals such as CdSe, carbon nanotubes, nanorods, nanowires, or a combination including at least one of the foregoing materials. In some embodiments, the electron accepting region may be made of a n-type semiconducting material such as, but not limited to, [6,6]-phenyl-C61-butyric acid methyl ester (PCBM) which is a fullerene derivative, or 3,4,9,10-perylene-tetracarboxyl-bis-benzimidazole (PTCBI). The material for the electron accepting region is not limited to the aforementioned examples, and any material or mixture having a higher electron affinity than that of the electron donating region can be used.

The electron donating region may absorb the incident light, thus forming excitons therein. An exciton is a bound state of an electron and a hole, and it diffuses in a random direction within the electron donating region. When an exciton in the electron donating region makes contact with a surface of the electron accepting region which has a relatively higher electron affinity, the exciton may be separated into an electron and a hole. That is, since the electron accepting region has a relatively higher electron affinity, it attracts the electron and induces a charge separation.

For example, due to a charge concentration difference and an internal electric field generated by a work function difference between the first electrode 120 and the second electrode 160, the hole may move toward the first electrode 120 and the electron may move toward the second electrode 160. The hole and the electron may flow as an electric current if an external load is coupled to the first electrode 120 and the second electrode 160. Power conversion efficiency (PCE) of the photovoltaic device 100 can be determined by the percentage of power converted (from absorbed light to electrical energy) and collected when the photovoltaic device 100 is coupled to an external load.

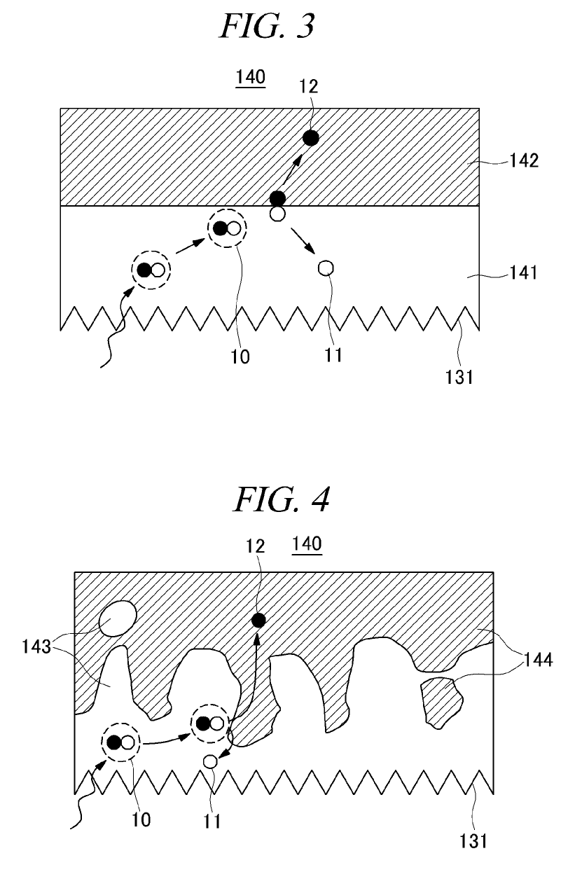

FIG. 3 is a schematic diagram of an illustrative embodiment of the photoactive layer 140. As depicted, the photoactive layer 140 includes an electron donating region 141 and an electron accepting region 142, which form a single layer. In particular, an interface between the electron donating region 141 and the electron accepting region 142 is substantially planar. As described above, an exciton 10 generated in the electron donating region 141 can be separated into a hole 11 and an electron 12 at the interface between the electron donating region 141 and the electron accepting region 142.

FIG. 4 is a schematic diagram of another illustrative embodiment of the photoactive layer 140. As can be seen from FIG. 4, a total area of an interface between electron donating regions 143 and electron accepting regions 144 is greater than that of the substantially planar interface shown in FIG. 3. Accordingly, the possibility of charge separation is higher in the illustrative embodiment shown in FIG. 4 than in the illustrative embodiment shown in FIG. 3. As a result, an electric current having a greater magnitude may be generated in the illustrative embodiment shown in FIG. 4. The increase in the magnitude of the electric current in turn increases the PCE of the photovoltaic device 100.

Further, the photoactive layer 140 may include a multiple number of electron donating regions 143 and a multiple number of electron accepting regions 144. For example, each of the electron donating regions 143 and the electron accepting regions 144 may be of a certain size or less. In this case, the electron donating regions 143 and the electron accepting regions 144 may be blended in the photoactive layer 140. When the electron donating regions 143 and the electron accepting regions 144 are blended, the total area of interfaces between the electron donating regions 143 and the electron accepting regions 144 are accordingly increased.

Increasing the excitons 10 generated in the photoactive layer 140 may also increase the PCE of the photovoltaic device 100. By way of example, but not limitation, more excitons 10 can be generated as a result of an increase of the light absorption in the photoactive layer 140. It will be appreciated that not all the incident light is absorbed in the photoactive layer 140, but some incident light passes right through the photoactive layer 140. Accordingly, the PCE can be increased if the photoactive layer 140 has a greater ability to absorb the light.

In one illustrative embodiment, an interface between the hole transport layer 130 and the photoactive layer 140 is in the form of the embossed pattern 131. The embossed pattern 131 may cause multiple diffractions, refractions or reflections of the incident light, which, in turn, induces various directions of light paths in photoactive layer 140. Accordingly, directions in which light passes through a particular region in the photoactive layer 140 can be varied. Therefore, light absorption property of the photoactive layer 140 can be enhanced as a result of the variation in directions of the light passing through a particular region in the photoactive layer 140.

Further, the multiple diffractions, refractions or reflections of the light allow the traveling distance of the light to be increased. If the interface between the hole transport layer 130 and the photoactive layer 140 is planar, the light will pass through the photoactive layer 140 by traveling a shorter distance. However, various directions of the light paths can increase the traveling distance of the light within the photoactive layer 140. As the traveling distance of the light is lengthened, the light absorption in the photoactive layer 140 increases, thereby causing an increase in the generation of the exciton 10.

By employing the embossed pattern 131, the amount of light absorbed by the photovoltaic device 100 can be increased while maintaining the other electrical or chemical properties of the photovoltaic device 100. Accordingly, the PCE of the photovoltaic device 100 can be readily enhanced without adding additional components to the photovoltaic device 100.

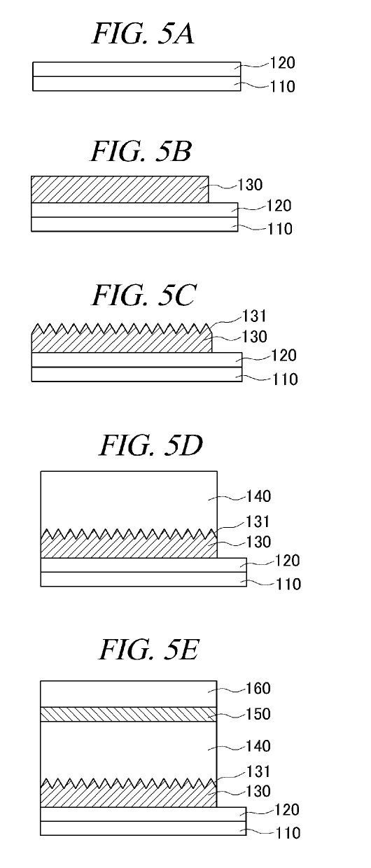

Although the embossed pattern 131 has been described to be positioned on the lower surface of the photoactive layer 140 in the above-described illustrative embodiments, the position of the embossed pattern 131 is not limited thereto. For example, in some embodiments, the embossed pattern 131 can be positioned anywhere within the photoactive layer 140. FIGS. 5A to 5E show an illustrative embodiment of a method for manufacturing a photovoltaic device, such as the photovoltaic device 100. As depicted in FIG. 5A, the first electrode 120 is formed on the transparent substrate 110. By way of example, but not limitation, the first electrode 120 may be formed by depositing a conductive material on the transparent substrate 110.

As depicted in FIG. 5B, the hole transport layer 130 is formed on the first electrode 120. For example, a solution suitable for forming the hole transport layer 130 may be supplied or deposited on the first electrode 120. One illustrative way of preparing the solution is to blend poly-3,4-ethylenedioxythiophene (PEDOT) with poly-styrenesulfonate (PSS) at a ratio of about 1:1. As described above, the material for forming the hole transport layer 130 is not limited to PEDOT:PSS. The hole transport layer 130 may be formed on the first electrode 120 by using any of a variety of well-known deposition or coating processes such as spraying, spin coating, dipping, printing, doctor blading, or sputtering, or through electrophoresis.

As depicted in FIG. 5C, the embossed pattern 131 is formed on an upper surface of the hole transport layer 130. The embossed pattern 131 can be formed by using any of a variety of well-known etching techniques such as photo-etching, ion beam etching, plasma etching, or the like. For example, if the hole transport layer 130 is made of PEDOT (or PEDOT:PSS), the embossed pattern 131 can be formed by using ultraviolet (UV) photo-etching.

As depicted in FIG. 5D, the photoactive layer 140 is formed on the embossed pattern 131 of the hole transport layer 130. The photoactive layer 140 can be formed by using any of the aforementioned well-known deposition or coating processes, or through electrochemical polymerization.

In some embodiments, an electron donating and an electron accepting materials may be deposited in sequence on the embossed pattern 131 of the hole transport layer 130 to form the photoactive layer 140. In such a case, the electron donating region forms a layer within the photoactive layer 140 while the electron accepting region forms another layer within the photoactive layer 140.

Alternatively, the photoactive layer 140 can include multiple electron donating regions and/or multiple electron accepting regions. Each of the electron donating regions or electron accepting regions may be of a certain size (for example, about 10 nm) or less, and can be blended in the photoactive layer 140. In such cases, a solution containing an electron donating material and an electron accepting material is prepared, and the photoactive layer 140 may be formed by using any of a variety of well-known techniques such as a spin coating, an ink jet printing, or a screen printing using the solution.

As depicted in FIG. 5E, the electron transport layer 150 and the second electrode 160 may be formed on the photoactive layer 140 in sequence. As described above, the electron transport layer 150 is optional and may be omitted. The electron transport layer 150, when present, and the second electrode 160 may be formed by using any of the aforementioned well-known deposition or coating processes. For example, if the electron transport layer 150 and the second electrode 160 are made of LiF and Al, respectively, the electron transport layer 150 and the second electrode 160 can be formed sequentially by using vacuum deposition.

As illustrated by FIGS. 5A to 5E, by adding to a conventional photovoltaic device manufacturing technique a process to form an embossed pattern, for example, on one surface of the photoactive layer, a photovoltaic device having an improved PCE can be readily manufactured.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

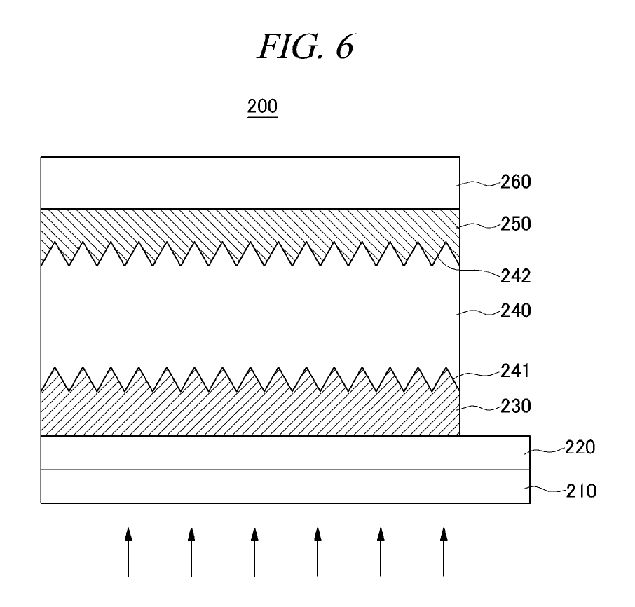

FIG. 6 is a schematic diagram of another illustrative embodiment of a photovoltaic device 200. As depicted, the photovoltaic device 200 may include a transparent substrate 210, a first electrode 220, a hole transport layer 230, a photoactive layer 240, an electron transport layer 250, and a second electrode 260.

Materials used for forming the transparent substrate 210, the first electrode 220, the hole transport layer 230, the photoactive layer 240, the electron transport layer 250 and the second electrode 260 may be similar to the materials used for forming the transparent substrate 110, the first electrode 120, the hole transport layer 130, the photoactive layer 140, the electron transport layer 150 and the second electrode 160 of the photovoltaic device 100 described in conjunction with FIG. 1, respectively.

In the photovoltaic device 200, a first embossed pattern 241 is formed at an interface between the hole transport layer 230 and the photoactive layer 240. Since the function and patterning process of the first embossed pattern 241 are similar to those of the embossed pattern 131 discussed above in conjunction with FIG. 1, redundant description thereof will be omitted herein.

Further, in the photovoltaic device 200, a second embossed pattern 242 may also be formed at an interface between the photoactive layer 240 and the electron transport layer 250. Alternatively, the second embossed pattern 242 can be formed at an interface between the photoactive layer 240 and the second electrode 260, if the electron transport layer 250 is omitted.

For example, the second embossed pattern 242 may have various patterns or shapes such as, by way of example, a triangular embossed pattern, a substantially rectangular embossed pattern, a polygonal embossed pattern, a semicircular embossed pattern and the like. The second embossed pattern 242 may include other kinds of patterns capable of inducing multiple diffractions, refractions or reflections of the incident light.

The second embossed pattern 242 can induce the multiple diffractions, refractions or reflections of the incident light, and suppress the light from passing right through the photoactive layer 240. That is, due to the multiple diffractions, refractions or reflections of the light, some of the light incident on the second embossed pattern 242 can be reflected toward the inside of the photoactive layer 240. Accordingly, the amount or level of light absorption in the photoactive layer 240 is increased because the second embossed pattern 242 may cause the reflection of the light. Increasing the amount of light absorption in the photoactive layer 240 may also increase the generation of excitons. Since the generated excitons are separated into electrons and holes, the second embossed pattern 242 can increase the PCE of the photovoltaic device 200.

The second embossed pattern 242 can be formed on an upper surface of the photoactive layer 240 by using any of a variety of well-known etching techniques such as photo-etching, ion beam etching, plasma etching or the like. For example, if the photoactive layer 240 is made of an organic material, the second embossed pattern 242 can be formed by a method such as, but not limited to, photo-etching using visible light.

The electron transport layer 250 may be formed on the second embossed pattern 242. However, the electron transport layer 250 is optional and may be omitted as discussed above. If the electron transport layer 250 is omitted, the second electrode 260 may be formed on the second embossed pattern 242. The second electrode 260 can be made of a conductive material having a work function lower than that of the first electrode 220. The second electrode 260 can be formed on the second embossed pattern 242 or the electron transport layer 250 by using any of the aforementioned well-known deposition or coating processes, or through electrophoresis.

As described above, a photovoltaic device can be manufactured by adding a process to form an embossed pattern, for example, on the upper surface of the photoactive layer to the processes described in FIGS. 5A to 5E.

It will be apparent to those skilled in the art that the above-described illustrative embodiments of the present disclosure can be also applied to an inorganic photovoltaic device, a dye sensitized photovoltaic device, or the like, as well as an organic photovoltaic device.

Furthermore, the illustrative embodiments of the present disclosure can be applied to a solar cell included in a solar battery. However, in addition to the photovoltaic device for use in the solar cell, the illustrative embodiments of the present disclosure can also be applied to various photovoltaic devices such as a photo-transistor, a photo-diode, a photo-coupler, a photo-relay, and so forth, to improve light absorption properties thereof.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds compositions or biological systems, which can, of course, vary. It is also to be understood that the terminology used herein is for the purpose of describing particular embodiments only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A photovoltaic device comprising a photoactive layer which has at least one embossed pattern on a first surface thereof.

2. The photovoltaic device of claim 1, wherein the photoactive layer includes at least one organic semiconductor material.

3. The photovoltaic device of claim 1, wherein the photoactive layer includes multiple number of electron donating regions and multiple number of electron accepting regions.

4. The photovoltaic device of claim 1, further comprising:
a transparent substrate;
a first electrode formed on the transparent substrate;
a hole transport layer formed on the first electrode; and
a second electrode,
wherein the photoactive layer is positioned between the hole transport layer and the second electrode.

5. The photovoltaic device of claim 4, further comprising:
an electron transport layer between the photoactive layer and the second electrode.

6. The photovoltaic device of claim 4, wherein the first surface is in contact with the hole transport layer and the at least one embossed pattern includes a first embossed pattern formed on the first surface of the photoactive layer.

7. The photovoltaic device of claim 6, wherein the first embossed pattern varies traveling directions of light incident to the first embossed pattern.

8. The photovoltaic device of claim 6, wherein the first embossed pattern increases traveling distances of light within the photoactive layer.

9. The photovoltaic device of claim 6, wherein the first embossed pattern includes at least one of a triangular pattern, a rectangular pattern, a polygonal pattern and a semicircular pattern.

10. The photovoltaic device of claim 6, wherein the at least one embossed pattern further includes a second embossed pattern formed on a second surface of the photoactive layer and the second surface is opposite to the first surface.

11. The photovoltaic device of claim 10, wherein the second embossed pattern reflects light incident to the second embossed pattern toward the inside of the photoactive layer.

12. A solar cell comprising:
a first electrode;
a second electrode; and
a photoactive layer, positioned between the first electrode and the second electrode, which includes an embossed pattern on a surface thereof facing a light source.

13. The solar cell of claim 12, wherein the photoactive layer further includes an embossed pattern on another surface thereof opposite to the surface facing the light source.

14. The solar cell of claim 12, wherein the embossed pattern varies traveling directions of light received through the first electrode.

15. A method for manufacturing a photovoltaic device, the method comprising:
preparing a hole transport layer;
patterning a first embossed pattern on a surface of the hole transport layer; and
forming a photoactive layer on the first embossed pattern.

16. The method of claim 15, wherein said forming the photoactive layer includes:
blending multiple number of electron donating regions with multiple number of electron accepting regions within the photoactive layer.

17. The method of claim 15, wherein said forming the photoactive layer includes:
forming a layer including an electron donating material; and
forming a layer including an electron accepting material.

18. The method of claim 15, further comprising:
patterning a second embossed pattern on a surface of the photoactive layer.

19. The method of claim 18, further comprising:
forming an electron transport layer on the second embossed pattern.

20. The method of claim 19, further comprising:
forming a first electrode below the hole transport layer; and
forming a second electrode on the electron transport layer.
